(19) United States
(12) Patent Application Publication
(10) Pub. No.: US 2013/0248995 A1
(43) Pub. Date: Sep. 26, 2013

(54) SEMICONDUCTOR DEVICE AND MANUFACTURING METHOD OF THE SAME

(71) Applicants: Tatsuya NISHIWAKI, Hyogo-ken (JP); Tsuyoshi Ota, Hyogo-ken (JP); Norio Yasuhara, Kanagawa-ken (JP); Masatoshi Arai, Hyogo-ken (JP); Takahiro Kawano, Kanagawa-ken (JP)

(72) Inventors: Tatsuya NISHIWAKI, Hyogo-ken (JP); Tsuyoshi Ota, Hyogo-ken (JP); Norio Yasuhara, Kanagawa-ken (JP); Masatoshi Arai, Hyogo-ken (JP); Takahiro Kawano, Kanagawa-ken (JP)

(73) Assignee: KABUSHIKI KAISHA TOSHIBA, Tokyo (JP)

(21) Appl. No.: 13/607,533

(22) Filed: Sep. 7, 2012

(30) Foreign Application Priority Data
Mar. 22, 2012 (JP) P2012-066416

(51) Int. Cl. H01L 29/78; H01L 21/82; H01L 27/088

(52) U.S. Cl. CPC H01L 29/7827; H01L 27/088; H01L 21/82
USPC 257/334; 438/270

(57) ABSTRACT

A semiconductor device includes a first semiconductor layer of a first conductivity type, a base layer of a second conductivity type placed above the first semiconductor layer, a second semiconductor layer of the first conductivity type placed above the base layer, multiple gate electrodes having upper end is positioned above the upper surface of the base layer, a lower end positioned below the bottom of the base layer, and contacting the first semiconductor layer, the second semiconductor layer, and the base layer through a gate insulating film, insulating component arranged above the gate electrode in which the upper surface is positioned below the upper surface of the second semiconductor layer, and a conductive layer covering the second semiconductor layer from the upper end to the bottom end.

### CROSS-REFERENCE TO RELATED APPLICATION

This application is based upon and claims the benefit of priority from Japanese Patent Application No. 2012-066416, filed Mar. 22, 2012; the entire contents of which are incorporated herein by reference.

### FIELD

Embodiments described herein relate to a semiconductor device and a manufacturing method of the same.

### BACKGROUND

In a trench type MOSFET (Metal-Oxide-Semiconductor Field-Effect Transistor), channel density is increased by refining the pitch of the trench where the gate electrodes are embedded in order to reduce the on-state resistance. To provide the desired channel density, a source layer is formed on the refined base layer. Additionally, in order to maintain a safe operating area of the unclamped inductive switching, it is necessary to form a base contact having a lower resistance than the refined base layer. However, it is difficult to form a source layer and base contact with extreme precision onto the refined base layer using conventional lithography methods.

### DESCRIPTION OF THE DRAWINGS

FIG. 1 is a sectional view showing a semiconductor device according to a first embodiment.

FIGS. 2A to 5 are schematic sectional views showing the manufacturing method of the semiconductor device of the first embodiment.

FIGS. 6A to 8D are schematic sectional views showing the manufacturing method of a semiconductor device according to a second embodiment.

FIG. 9 is a sectional view showing a semiconductor device according to a third embodiment.

FIGS. 10A to 10D are the flow plan view showing the manufacturing method of the semiconductor device of the third embodiment.

FIGS. 11A to 11D are the flow sectional view showing the manufacturing method of the semiconductor device of the third embodiment.

FIGS. 12A to 14B are schematic sectional views showing the manufacturing method of the semiconductor device of the third embodiment.

FIGS. 15A to 19B are schematic sectional views showing the manufacturing method of a semiconductor device according to a fourth embodiment.

### DETAILED DESCRIPTION

In general, according to one embodiment, an example will be described in reference to the figures.

According to the embodiment, there is provided an improved semiconductor device and a manufacturing method thereof.

A semiconductor device according to one embodiment includes a first semiconductor layer of first conductivity type, a base layer of second conductivity type that is set on top of first semiconductor layer, a second semiconductor layer of first conductivity type set on top of the base layer, multiple gate electrode in which the upper end is positioned above the upper surface of the base layer, the lower end is positioned below the bottom surface of the base layer, comes in contact with the first semiconductor layer, the second semiconductor layer, and the base layer through the gate insulating film, an insulating component placed on top of the gate electrode in which the top surface is position below the top surface of the second semiconductor layer, a conductive layer between the gate electrodes, partitioned a certain distance from the electrode, covering from top to bottom of the second semiconductor layer and the upper end of the second semiconductor layer and the insulating component.

A manufacturing method of a semiconductor device of this embodiment includes a process forming multiple first masks on the semiconductor substrate stretching in one direction, a process forming second mask on the lateral surface of the first mask, a process forming a first trench on the upper surface of the semiconductor substrate using the first mask and second mask as masks, a process to embed insulating components to the first trench, a process to remove the first mask, and a process forming a second trench which is shallower than the first trench by etching the upper surface of the semiconductor substrate using the second mask and the insulating components as masks.

### Embodiment 1

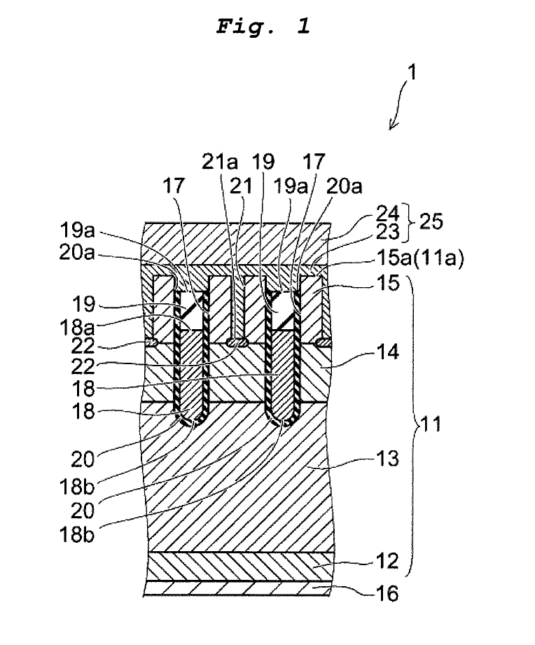

From here on, reference to the FIGS. will be provided to further explain the mode for carrying out the invention. Embodiment 1 will be explained. FIG. 1 is a sectional view showing the semiconductor device relating to the first embodiment. As shown in FIG. 1, semiconductor substrate 11 is formed as a portion of a semiconductor device 1 relating to this embodiment. Semiconductor substrate 11 is a silicon substrate composed of, for example, single crystal silicon. Semiconductor substrate 11 is comprised of, from the bottom layer and up, a drain layer 12, a drift layer 13, a base layer 14, and a source layer 15 in this order. A drain electrode 16 is placed at the bottom surface of semiconductor substrate 11. Drain electrode 16 is for example, a metal film in contact with the entire bottom surface of semiconductor substrate 11.

In drain layer 12, an impurity (e.g., dopant), such as phosphorus, is contained as the donor. Drain layer 12 has an n-type conductivity. Drift layer 13 is formed on drain layer 12. In the drift layer 13, an impurity such as phosphorus, is contained as the donor. Drift layer 13 has an n-type conductivity. However, the effective impurity concentration of drift layer 13 is lower than the effective impurity concentration of drain layer 12.

Now, “effective impurity concentration” within this specification refers to the dopant concentration that determines the conductivity of the semiconductor material. For example, if in the case where both donor and acceptor impurities are included in the semiconductor material, then the concentration is the amount after removing the offset of the donor and acceptor.

Base layer 14 is formed on drift layer 13. In base layer 14, an impurity such as boron is contained as the acceptor. Base layer 14 has a p-type conductivity. Source layer 15 is formed on base layer 14. In source layer 15, an impurity such as phosphorus is contained as the donor. Source layer 15 has an n-type conductivity.

Gate electrodes 18 are formed on the interior of semiconductor substrate 11.

Gate electrodes 18 are composed of conductive material such as doped poly-silicon. The bottom end of gate electrodes 18 are positioned within drift layer 13, the intermediate part of gate electrode 18 extends through the base layer 14, and the upper end of gate electrode 18 is positioned within and/or between the source layer 15. The upper end 18a of each gate electrode 18 is positioned above the upper surface of base layer 14 and the bottom surface of source layer 15. The bottom end 18b of each gate electrode 18 is positioned below the bottom surface of base layer 14.

Gate electrodes 18 are formed within insulating component layer 19 which is composed of an insulating material such as silicon oxide (e.g., SiO₂). Upper surface 19a of insulating component layer 19 is positioned below the upper surface 15a of source layer 15.

Intermediate of semiconductor substrate 11 and gate electrodes 18 and insulating component layer 19, a gate insulating film 20 is formed, which is composed of an insulating material such as silicon oxide (e.g., SiO₂). Each gate electrode 18 is in electrical contact with drift layer 13, base layer 14, and source layer 15 through the gate insulating film 20. Upper end 20a of gate insulating film 20 is also positioned below the upper surface 15a of source layer 15.

Conductive layer 23 is formed on semiconductor substrate 11. Conductive layer 23 can be for example, tungsten film. Conductive layer 23 is connected with the entire upper surface of semiconductor substrate 11 and the entire upper surface 19a of insulating component layer 19. Therefore, the conductive layer 23 covers the upper surface 15a of the source layer 15 and the insulating component layer 19. Additionally, among gate electrodes 18, conductive layer 23 is partitioned a certain distance from the gate electrodes 18, covering, from top to bottom, the source layer 15. Conductive layer 23 is mounted with metal film 24 composed of metal such as aluminum. A source electrode 25 is formed consisting of the conductive layer 23 and the metal film 24.

Base contact layer 22 is positioned at the boundary of source layer 15 and base layer 14 to be in contact with conductive layer 23. Conductivity type of base contact layer 22 is p-type. However, the effective impurity concentration of base contact layer 22 is higher than the effective impurity concentration of base layer 14. In semiconductor device 1, the structure shown in FIG. 1 is repeatedly arranged. FIG. 1 represents only two such base units.

Next, the operation of the semiconductor device relating to this embodiment will be explained. In semiconductor device 1, when negative electric potential is applied to source electrode 25 and when positive electric potential is applied to drain electrode 16, depletion layer is formed at the origin, which may be the interface of drift layer 13 and base layer 14. At this state, if electric potential is higher than the threshold value is applied to gate electrodes 18, inversion layer is formed proximate to gate insulating film 20 in base layer 14, and electric current flows from drain electrode 16 through drain layer 12, drift layer 13, base layer 14, then to source layer 15. On the other hand, if electric potential lower than the threshold value is applied to gate electrodes 18, the inversion layer does not form and electric current is cut off. When this occurs, a positive hole generated within semiconductor substrate 11 is rapidly discharged to source electrode 25 through base contact layer 22.

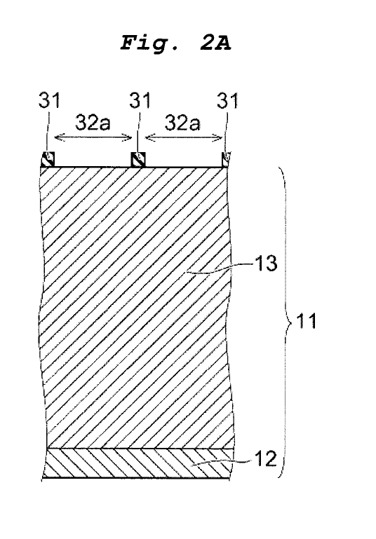

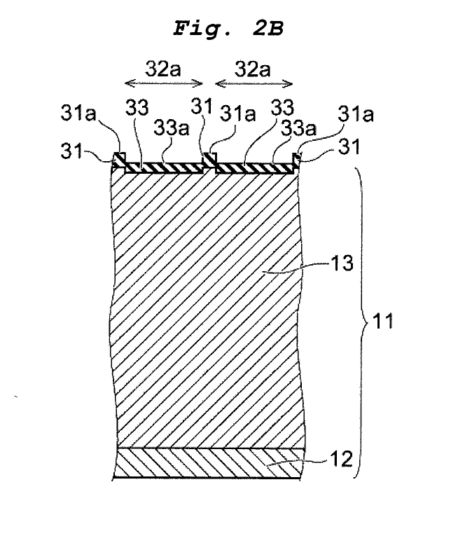

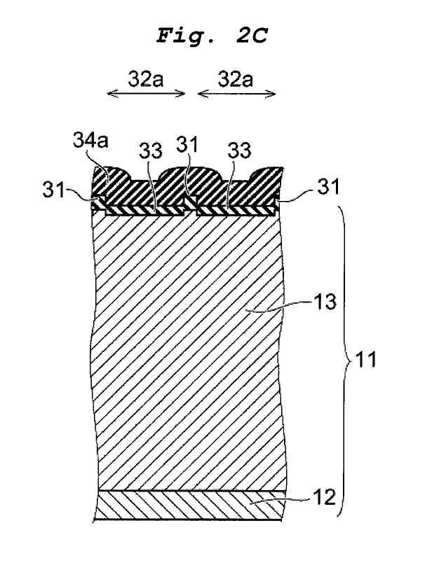

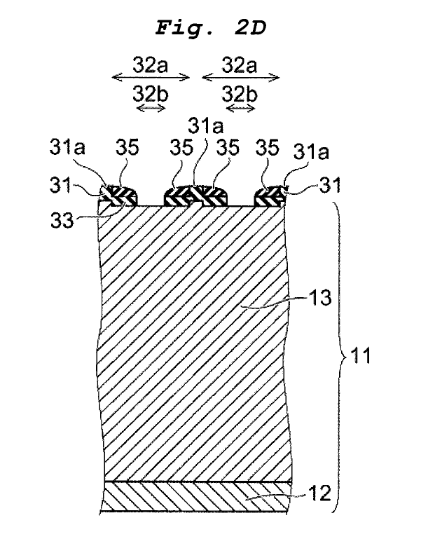

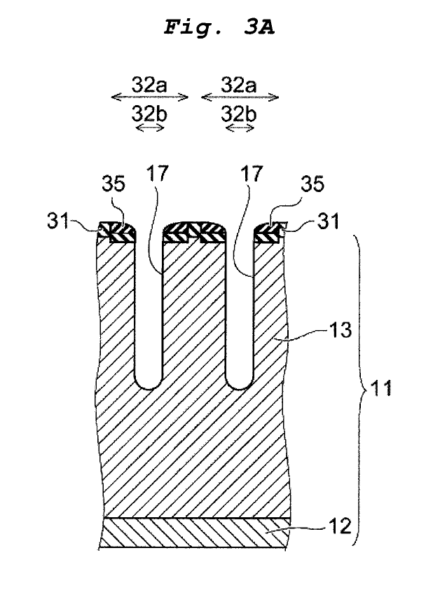

Next, the manufacturing method of the semiconductor device relating to this embodiment will be explained. FIGS. 2A to 2D, FIGS. 3A to 3D, FIGS. 4A to 4D, and FIG. 5 are the schematic sectional views showing steps of the manufacturing method of the semiconductor device relating to the embodiment 1.

First, a semiconductor substrate 11 is formed as shown in FIG. 2A. A drift layer 13 formed on top of drain layer 12 which comprises the semiconductor substrate 11. Drain layer 12 and drift layer 13 are doped to have an n-type conductivity. However, the effective impurity concentration of drift layer 13 is lower than the effective impurity concentration of drain layer 12.

Next, a silicon oxide film is formed above semiconductor substrate 11 by methods such as thermal oxidation or CVD (Chemical Vapor Deposition). Next, using lithography methods, the blanket SiO₂ film is selectively removed to form a plurality of first mask portions 31. Between first mask portions 31, a first open region 32a is formed on the upper surface of semiconductor substrate 11. Next, as shown in FIG. 2B, an insulating film 33 is formed on semiconductor substrate 11 in the first open regions 32a by method such as thermal oxidation. The insulating film 33 is formed so that an upper surface 33a thereof is located below an upper surface 31a of the first mask portions 31 in a non-planar orientation.

After that, a silicon nitride film 34a is formed on the entire surface as shown in FIG. 2C. This silicon nitride film 34a covers insulating film 33 in the open regions 32a as well as the first mask portions 31.

Next, as shown in FIG. 2D, etch-back techniques are applied to remove the section of the silicon nitride film 34a formed above the upper surface 31a of the first mask portions 31 and the flat section above the insulating film 33, the remainder of which is retained on the lateral surface of first mask portions 31. By doing this, a plurality of second mask portions 35 are formed. Second mask portions 35 are formed on the lateral surface of first mask portions 31, and a second open region 32b is formed within first open region 32a. Then, portions of insulating film 33 (shown in FIG. 2C) in the second open region 32b may be removed using second mask portions 35 as a mask.

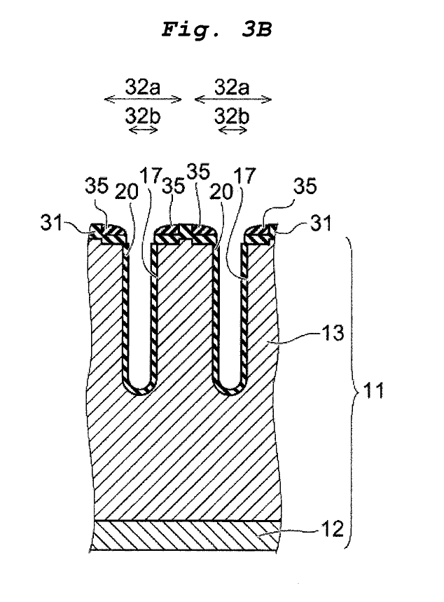

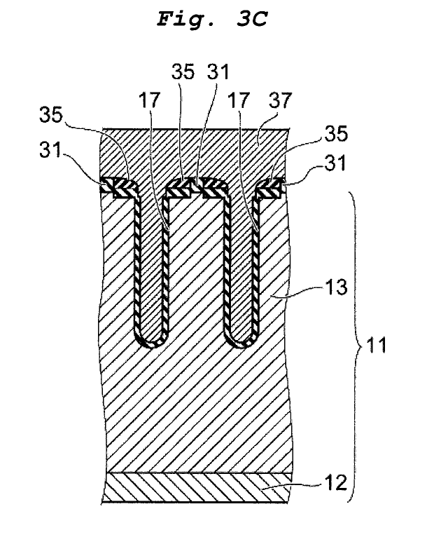

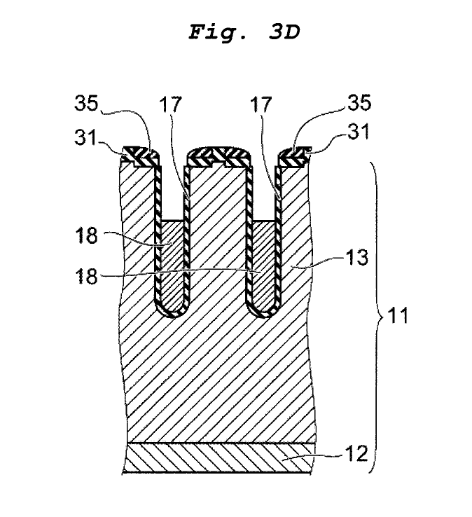

Next, as shown in FIG. 3A, by using first mask portions 31 and second mask portions 35 as a mask to apply anisotropic etching techniques such as RIE (Reactive Ion Etching) to selectively remove portions of the drift layer 13 positioned within second open region 32b in the upper end of semiconductor substrate 11 in order to form multiple first trenches 17 in equal intervals stretching in one direction in the drift layer 13.

Next, as shown in FIG. 3B, form gate insulating film 20 is formed on the interior of each first trench 17 by using a method such as thermal oxidation process. In the case where the gate insulating film 20 is formed by thermal oxidation process, the lateral surface (i.e., sidewalls) of first trench 17 will be oxidized and eroded. Because of this, the width of first trench 17 sidewalls will be larger than the width of second open region 32b. However, the thickness of the gate insulating film 20 may decrease the width of each first trench 17 to be substantially equal to or less than the width of the second open region 32b.

Next, as shown in FIG. 3C poly-silicon film 37 is formed by building up impurity such as poly-silicon containing phosphorus on the entire surface of the semiconductor substrate 11. This poly-silicon film 37 is embedded onto first trench 17 and built up on the upper surface of first mask portions 31 and second mask portions 35. Next, as shown in FIG. 3D, etch-back is applied to remove the section of poly-silicon film 37 (shown in FIG. 3C) built up on the upper surface of first mask portions 31 and second mask portions 35 along with an upper portion of the poly-silicon film 37 embedded onto first trench 17. As a result, the poly-silicon film 37 remaining on the bottom portion of each first trench 17 forms the gate electrodes 18.

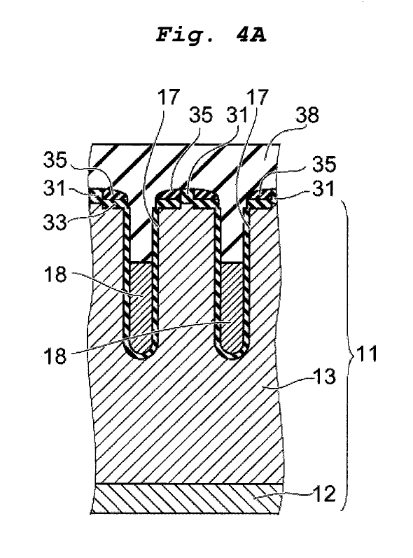

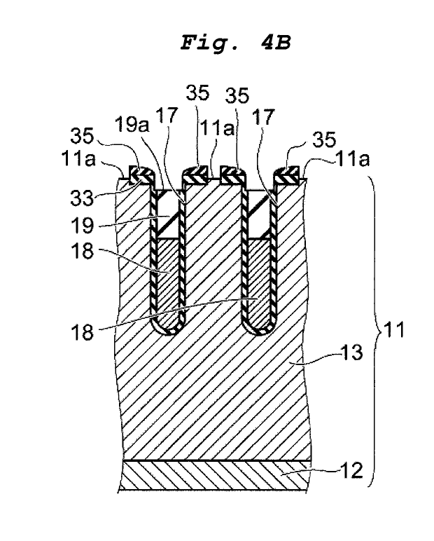

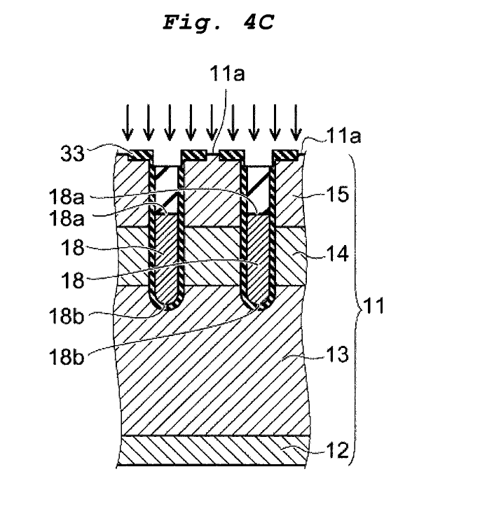

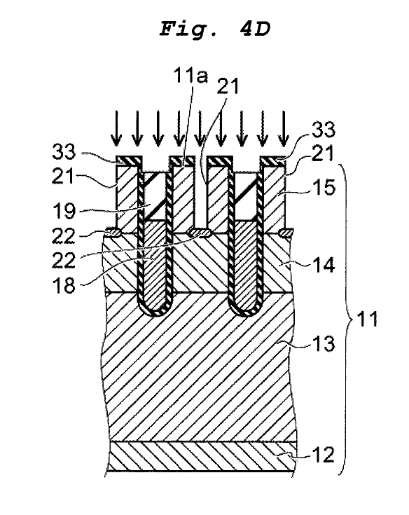

Next, as shown in FIG. 4A, a silicon oxide film 38 is formed by depositing silicon oxide on the entire surface of the semiconductor substrate 11 using a deposition method such as the CVD method. Silicon oxide film 38 is embedded above the gate electrode 18 section within first trench 17 and arranged above the upper surface of first mask portions 31 and second mask portions 35.

Next, as shown in FIG. 4B, etch-back is performed on the entire surface of the semiconductor substrate 11 to remove the portions of the silicon oxide film 38 (shown in FIG. 4A) above the upper layer of first mask portions 31 (also shown in FIG. 4A). A portion of the second mask portions 35 as well as the region directly above first trench 17 is also removed. By doing this, silicon oxide film 38 (shown in FIG. 4A) remains within first trench 17 to form the insulating component layer 19. In this case, the upper surface 19a of insulating component layer 19 is below the upper surface 11a of semiconductor substrate 11. Additionally, first mask portions 31 (shown in FIG. 4A) are removed and the section where first mask portions 31 are arranged in upper surface 11a of semiconductor substrate 11 will be exposed. After that, second mask portions 35 are removed with the insulating film 33 remaining.

Next, as shown in FIG. 4C, a dopant, such as boron, which is the impurity that becomes the acceptor, is ion implanted in the semiconductor substrate 11 from the upper side of the semiconductor substrate 11 by implant techniques. Because of this, conductivity of the section above the lower end 18b of gate electrodes 18 in the semiconductor substrate 11 changes from n-type to p-type. Thus, base layer 14 is formed at the upper layer of semiconductor substrate 11.

Additionally, a dopant, such as phosphorus, which is the impurity that becomes the donor, is ion implanted in semiconductor substrate 11 from the upper side of the semiconductor substrate 11. Because of this, conductivity of upper layer of base layer 14 changes from p-type to n-type and becomes the source layer 15. The bottom surface of source layer 15 is positioned below the upper surface 18a of gate electrode 18 in a non-planar arrangement.

Next, as shown in FIG. 4D, using the insulating film 33 as a mask, anisotropic etching is performed from the upper side of the semiconductor substrate 11. From this, the region covered by the first mask portions 31 in semiconductor substrate 11 is selectively removed, and a second trench 21 is formed stretching in one direction on the upper surface 11a of semiconductor substrate 11. The second trench 21 is formed to be deep enough to penetrate through source layer 15 and reach base layer 14. Second trenches 21 extend inwardly of source layer 15 at least directly adjacent to, or up to, base layer 14. However, each second trench 21 may further extend into base layer 14. Trenches 21 are formed in between each first trench 17. Therefore, first trench 17 and second trench 21 are arranged alternately.

Next, using insulating film 33 and insulating component layer 19 as a mask, the impurity that becomes the acceptor is ion implanted in semiconductor substrate 11. From this, the base contact layer 22 is formed. Base contact layers 22 include a p-type conductivity and an effective impurity concentration that is greater than the effective impurity concentration of base layer 14. Each base contact layer 22 is formed at region directly below second trench 21, that is the region underneath source layer 15 in base layer 14. Additionally, when ion species capable of only shallow implant depth such as BF₂ is used as the impurity that becomes the acceptor, it is very rare for insulating film 33 above source layer 15 to become the mask and ion implanted against source layer 15. On the other hand, when ion species with capable of deeper implant depth such as boron is used, even though boron may be implanted to source layer 15, source layer 15 contains high density phosphorus. Since the amount of boron implanted in this process is less than the amount of phosphorus contained in source layer 15, conductivity type of source layer 15 will not change from n-type to p-type by this boron implant process.

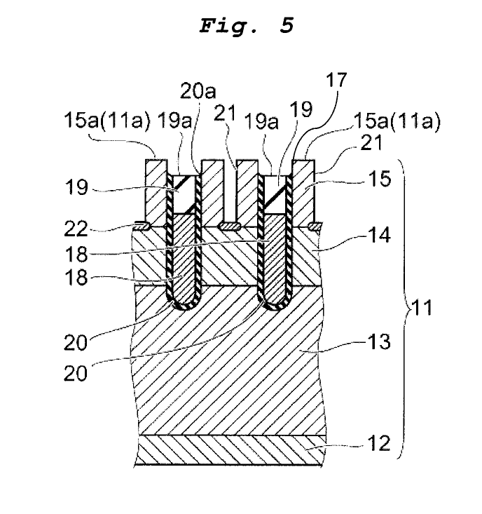

Next, as shown in FIG. 5, etch-back is applied to semiconductor substrate 11 under the condition in which component layer 19, gate insulating film 20, and insulating film 33 (shown in FIG. 4D) are selectively etched to remove upper part of insulating component layer 19, upper part of gate insulating film 20, and insulating film 33. From this, upper end 20a of gate insulating film 20 is stripped below upper surface 11a of semiconductor substrate 11 that is, below upper surface 15a of source layer 15. Additionally, upper part of sidewall surfaces of first trench 17 within source layer 15 and upper surface 15a of source layer 15 will be exposed.

Next, as shown in FIG. 1, conductive layer 23 is formed covering the upper surface of semiconductor substrate 11. Conductive layer 23 enters second trench 21 and comes in contact with the upper surface of base contact layer 22, along with the entire exposed surface of source layer 15, additionally, upper surface 19a of insulating component layer 19 and upper end 20a of insulating film 20 comes in contact as well. Next, metal film 24 is formed on conductive layer 23 by deposition methods. Source electrode 25 is formed consisting of the conductive layer 23 and the metal film 24. On the other hand, drain electrode 16 is formed at the bottom surface of the semiconductor substrate 11.

This is how semiconductor device 1 is manufactured as shown in FIG. 1.

Next, the effect of this embodiment will be explained.

In this embodiment, upper surface 15a of source layer 15 is above the upper surface 19a of insulating component layer 19 of the first trench 17, and upper surface 15a of source layer 15 is above the upper surface of base contact layer 22 of the second trench 21. Therefore, source layer 15 is structured projecting above the insulating component layer 19 and base contact layer 22. Hence, the area of contact between source layer 15 and source electrode 25 is dramatically increased. From this, source contact resistance is decreased, and even after refinement, a semiconductor device 1 having a low on-state resistance may be realized.

Again, for the manufacturing method in this embodiment, in the process shown in FIG. 2A, first mask portions 31 are formed on semiconductor substrate 11, in the process shown in FIG. 2D, insulating film 33 and second mask portions 35 are formed on the lateral surfaces of first mask portions 31, in the process shown in FIG. 3A, first trenches 17 are formed using first mask portions 31 and second mask portions 35 as masks, in the process shown in FIG. 4D, second trenches 21 are formed using insulating film 33 as a mask.

Once the first mask portions 31 are formed using lithography methods, first trench 17 and second trench 21 may be formed to be self-aligned in this manner. During this process, opening width of second trench 21 is controlled by the width of first mask portions 31, and the opening width of first trench 17 is controlled by the interval of first mask portions 31 and the width of second mask portions 35.

As the first trench 17 and second trench 21 may be formed by self-alignment, the source layer 15, formed in between first trench 17 and second trench 21, may also be self-aligned. While lithography may be used to form the termination region to ensure good breakdown voltage, the source layer 15 may be formed without utilizing lithography methods. During this process, the width of source layer 15 may be controlled by the width of second mask portions 35 and width of insulating film 33.

Additionally, using insulating film 33 that is self-aligned as described above, as a mask, base contact layer 22 may also be formed by self-alignment.

By using similar materials for first mask portions 31 and for insulating component layer 19, removal of first mask portions 31 and formation of insulating component layer 19 can be performed concurrently in the same process. When forming base layer 14 and source layer 15, ion implantation is performed using insulating film 33 which protects ions from being deeply implanted along a particular mono-crystal plane. The insulating film 33 also acts as a cap layer to prevent ions from escaping due to heat treatment. From this, ion implantation depth as well as the ion concentration can be controlled.

Additionally, although in this embodiment, second mask portions 35 are removed and base layer 14 and source layer 15 are formed, second mask portions 35 do not have to be removed. For example, second mask portions 35 may be used as a mask when forming second trenches 21. Also, the depth of each first trench 17 is set to enter the drift layer 13, the depth can be just enough to reach the drift layer 13. The depth of second trenches 21 is set to reach the base layer 14, the depth can also be set to extend at least partially into the base layer 14.

### Embodiment 2

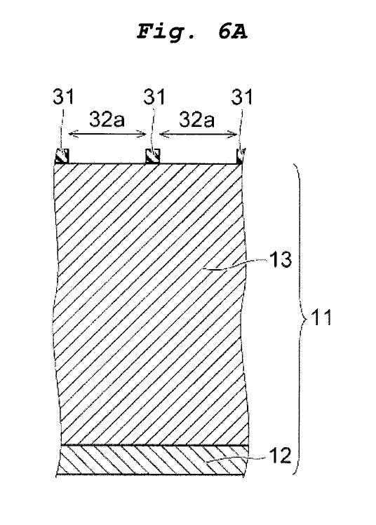

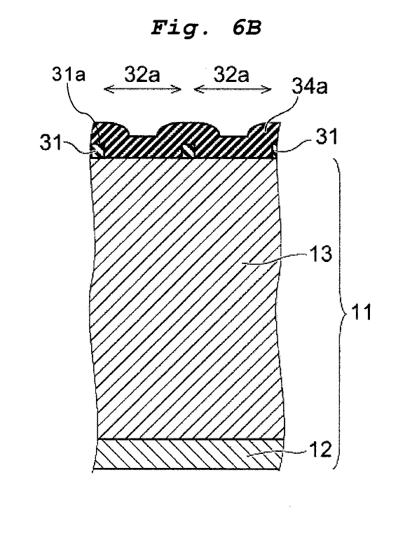

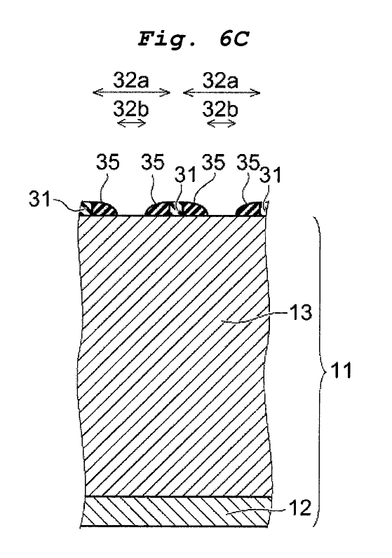

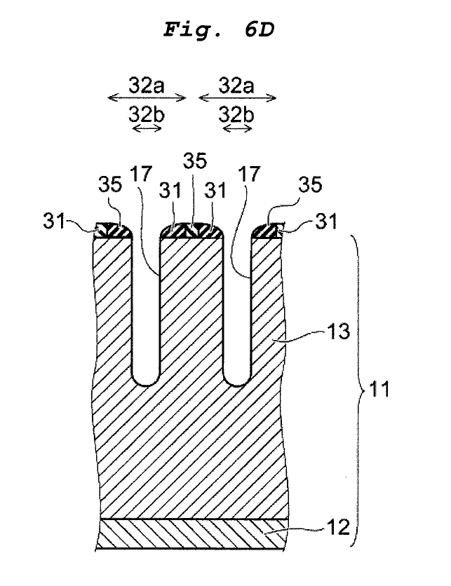

Next, embodiment 2 will be explained. FIGS. 6A to 6D, FIGS. 7A to 7D, FIGS. 8A to 8D are schematic sectional views showing steps of a manufacturing method of the semiconductor device relating to the second embodiment.

This embodiment is the manufacturing method of semiconductor device 1 where insulating film 33 is not formed on the semiconductor substrate 11 as described in the first embodiment.

First, a semiconductor substrate 11 is formed as shown in FIG. 6A. Next, first mask portions 31 are formed on the semiconductor substrate 11. And then a silicon nitride film 34a is formed on the entire surface of semiconductor substrate 11 as shown in FIG. 6B. This silicon nitride film 34a covers semiconductor substrate 11, first open regions 32a and first mask portions 31.

Next, as shown in FIG. 6C, etch-back is applied to remove the section of the silicon nitride film 34a formed above the upper surface 31a of the first mask portions 31 and the silicon nitride film 34a section above the semiconductor substrate 11 (shown in FIG. 6B), and the remaining silicon nitride film 34a on the lateral surfaces of first mask portions 31 form second mask portions 35. Second mask portions 35 are formed on the lateral surface of first mask portions 31, and a second open region 32b is formed within first open region 32a.

Next, as shown in FIG. 6D, using first mask portions 31 and second mask portions 35 as a mask, first trenches 17 are formed.

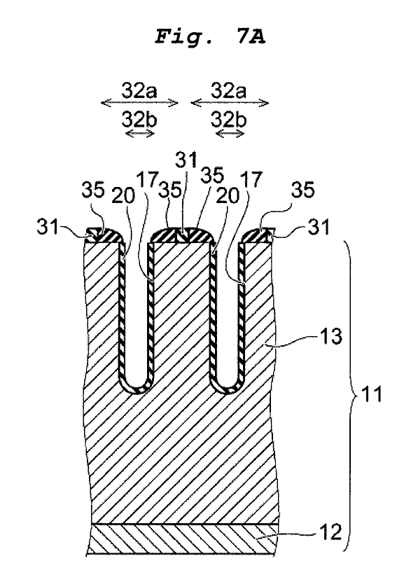

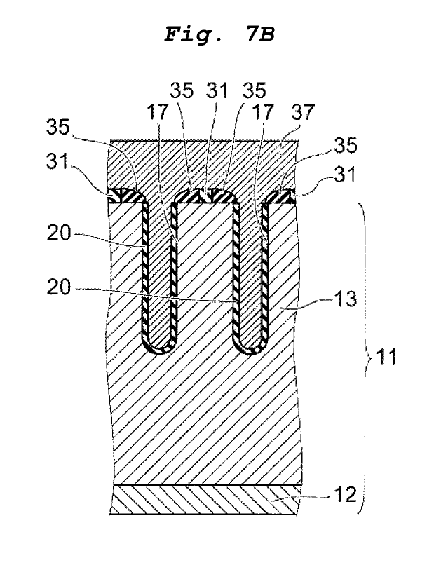

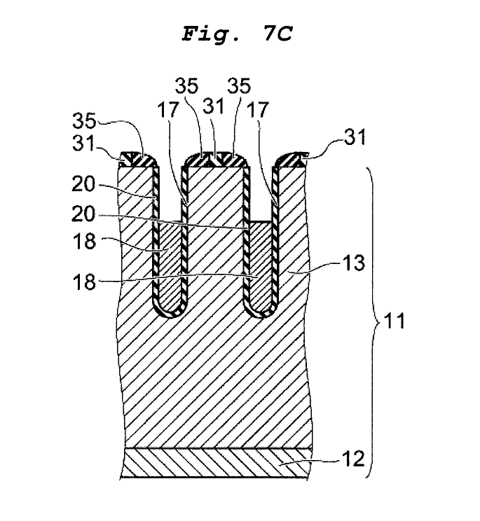

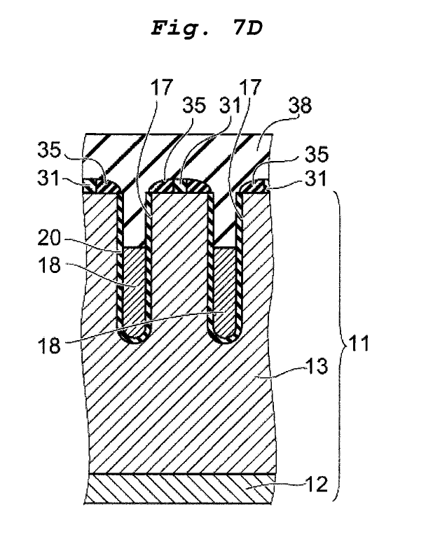

Next, as shown in FIG. 7A, gate insulating film 20 is formed on the interior of each first trench 17. And then, as shown in FIG. 7B, poly-silicon film 37 is formed on semiconductor substrate 11 embedding the each first trench 17.

Next, as shown in FIG. 7C, etch-back is applied and poly-silicon film 37 (shown in FIG. 7B) is stripped leaving a portion remaining on the bottom of first trenches 17, thus forming gate electrodes 18. Next, as shown in FIG. 7D, silicon oxide film 38 is formed on semiconductor substrate 11 embedding the first trenches 17.

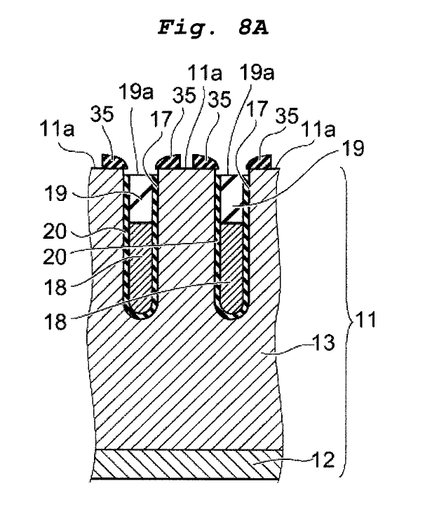

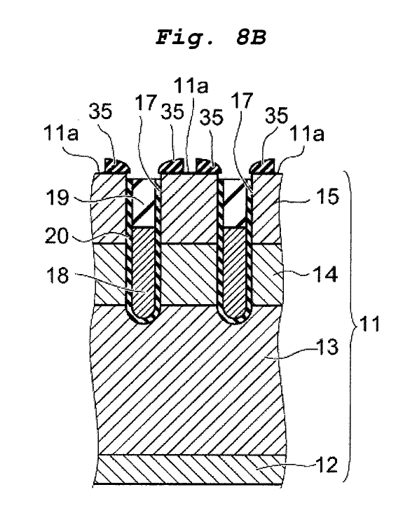

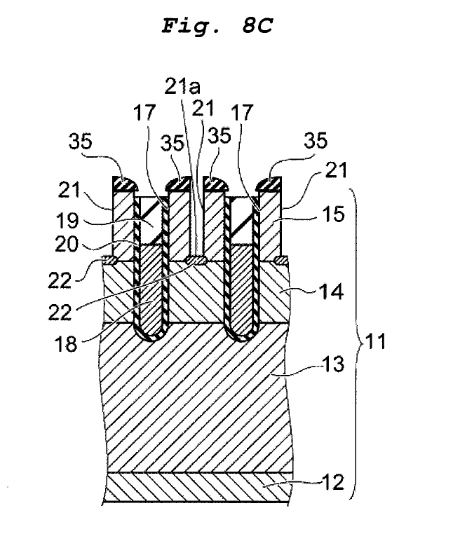

Next, as shown in FIG. 8A, etching is performed on the entire surface and silicon oxide film 38 (shown in FIG. 7D) is stripped leaving a portion remaining in the first trenches 17, thus forming insulating component layer 19 on the gate electrodes 18. Again, during this time, the first mask portions 31 (shown in FIG. 7D) are removed.

Next, as shown in FIG. 8B, boron is ion implanted into semiconductor substrate 11 from above to form base layer 14. Additionally, phosphorus is ion implanted into semiconductor substrate 11 from above to form source layer 15.

Next, as shown in FIG. 8C, using second mask portions 35 as a mask, anisotropic etching is performed from above semiconductor substrate 11. From this, the sections of upper surface 11a (shown in FIG. 8B) that were covered by first mask portions 31 (shown in FIG. 7D) in semiconductor substrate 11 are selectively removed, and second trenches 21 are formed stretching in one direction in semiconductor substrate 11.

Next, using second mask portions 35 and insulating component layer 19 as a mask, the p-type impurity that becomes acceptor is ion implanted into semiconductor substrate 11. From this, base contact layer 22 is formed at the region directly under second trenches 21.

Next, as shown in FIG. 8D, second mask portions 35 (shown in FIG. 8C) are removed by a stripping method. Additionally, the upper part of insulating component layer 19 and the upper part of gate insulating film 20 is removed. From this, upper surface 19a of insulating component layer 19 and upper end 20a of gate electrode 20 is set below upper surface 11a of semiconductor substrate 11 (i.e., below upper surface 15a of source layer 15).

Next, as shown in FIG. 1, source electrode 25 is formed covering the upper surface of semiconductor substrate 11, and drain electrode 16 is formed on the bottom surface of semiconductor substrate 11. Semiconductor device 1 is manufactured in this manner as shown in FIG. 1.

Next, the effect of this embodiment will be explained. In this embodiment, it is not necessary to form insulating film 33. Thus, the effects of this embodiment may be the same as the first embodiment, with the additional benefit of minimized manufacturing steps and a decrease in manufacturing costs due to the minimal manufacturing steps.

### Embodiment 3

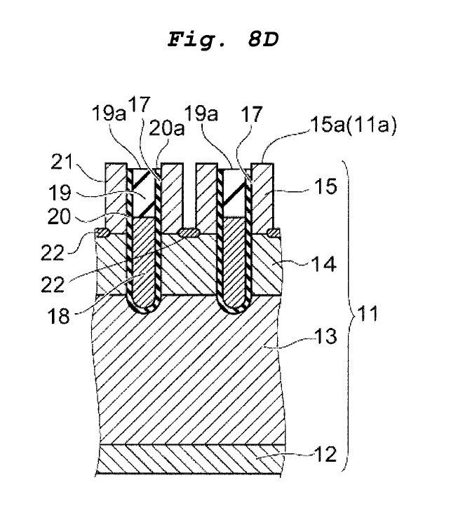

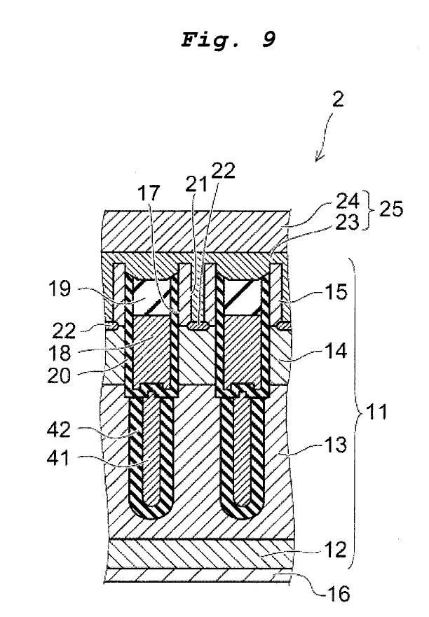

Next, embodiment 3 will be explained. FIG. 9 is a sectional view showing the semiconductor device relating to the third embodiment. As shown in FIG. 9, the semiconductor device 2 relating to this embodiment is distinguished from the semiconductor device 1 shown in FIG. 1, the difference being that there is a field plate electrode 41 formed in the region directly below the gate electrodes 18. Field plate electrode 41 is composed of conductive material such as doped poly-silicon and is connected to source electrode 25 or gate electrode 18 (connection not shown). On the other hand, field plate electrode 41 is electrically isolated from drain electrode 16. A field plate insulating film 42 is formed in between field plate electrode 41 and drift layer 13. In this embodiment, everything except for the field plate electrode 41 and the field plate insulating film 42 is the same in structure as the first embodiment.

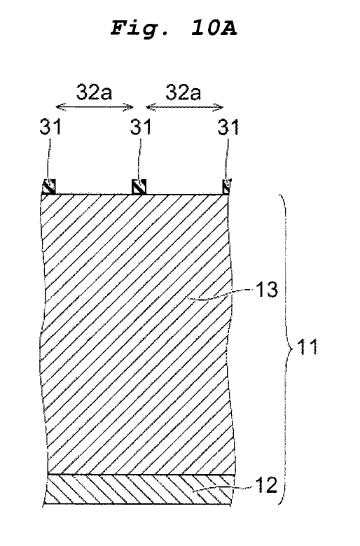

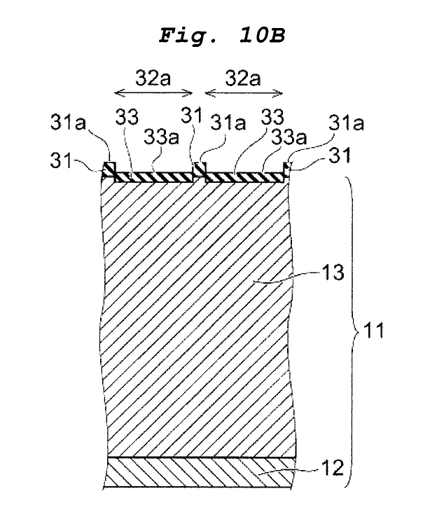

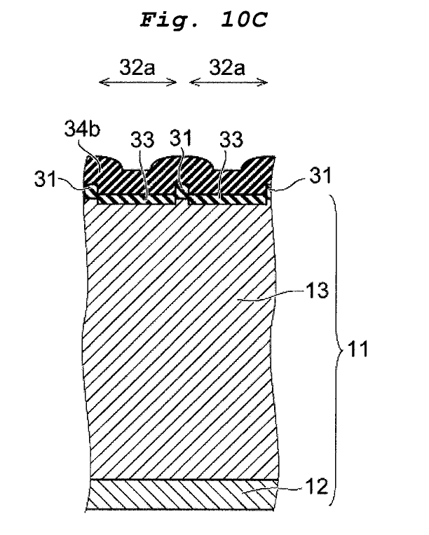

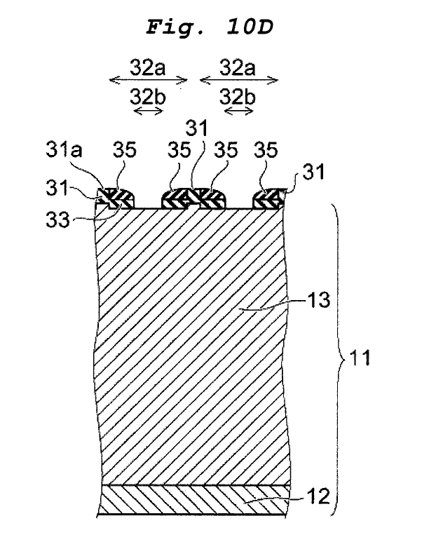

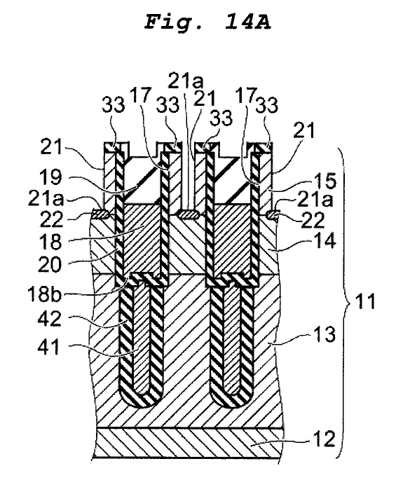

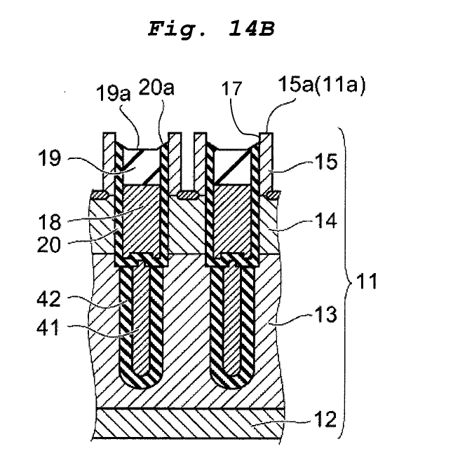

Next, a manufacturing method of the semiconductor device 2 relating to this embodiment will be explained. FIGS. 10A to 10D, FIGS. 11A to 11D, FIGS. 12A to 12D, FIGS. 13A to 13D, along with FIGS. 14A and 14B are schematic sectional views showing the manufacturing method of the semiconductor device relating to the third embodiment.

First, as shown FIGS. 10A and 10B, the process shown in FIGS. 2A and 2B from the first embodiment 1 will be utilized and an explanation for these procedures will be omitted for brevity. As shown in FIG. 10C, silicon nitride film 34b is formed on the entire surface of semiconductor substrate 11. This silicon nitride film 34b covers insulating film 33 in the first open region 32a between first mask portions 31. In this embodiment, the thickness of silicon nitride film 34b is made thicker than the thickness of silicon nitride film 34a in the first embodiment (shown in FIG. 2C).

Next, as shown in FIG. 10D, etch-back is applied to remove the section of the silicon nitride film 34b (shown in FIG. 10C) formed above the upper surface 31a of the first mask portions 31 and the section above the insulating film 33, the remainder of the silicon nitride film 34b being maintained on the lateral surface of first mask portions 31. By doing this, second mask portions 35 are formed. Then, second mask portions 35 are used as a mask to remove the section of semiconductor substrate 11 in the second open region 32b.

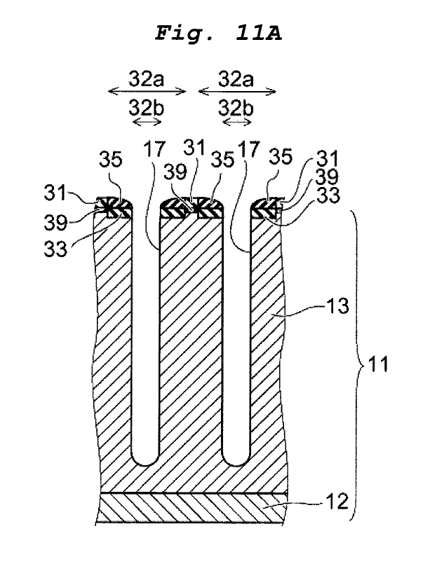

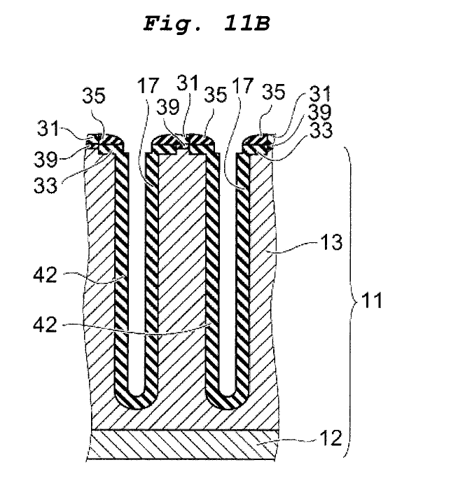

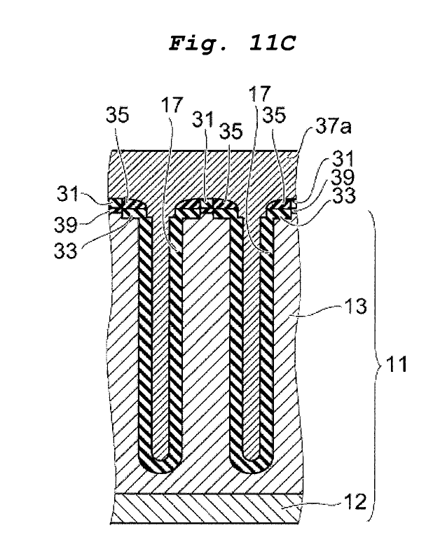

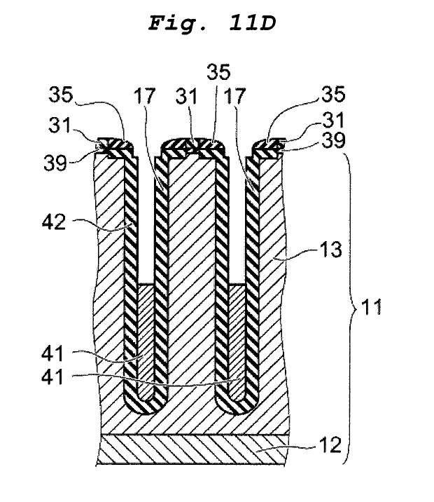

Next, as shown in FIG. 11A, using first mask portions 31 and second mask portions 35 as a mask to apply anisotropic etching techniques such as RIE, first trenches 17 are formed having a greater aspect ratio as compared to the semiconductor device 1 of the first embodiment.

Next, as shown in FIG. 11B, a field plate insulating film 42 is formed on the interior of first trenches 17 by using methods such as thermal oxidation processes. The thickness of the field plate insulating film 42 may be greater than the thickness of the gate insulating film 20 (shown in FIG. 3B). During this process, the section covered by first mask portions 31 in the upper surface of semiconductor substrate 11 is also oxidized, forming an insulating film 39. When field plate insulating film 42 is formed by thermal oxidation process, the lateral surface (i.e., sidewalls) of first trenches 17 will be oxidized and eroded. Field plate insulating film 42 is made thicker than the gate insulating film 20 in the first embodiment. As a result, the thickness of the lateral surface of first trenches 17 that are being eroded is also greater than that of gate insulating film 20. From this, the width of the sidewall of first trenches 17 is wider than the width of the second open region 32b (shown in FIG. 11A). However, the thickness of the field plate insulating film 42 may decrease the width of each first trench 17 to be substantially equal to or less than the width of the second open region 32b. Additionally, field plate insulating film 42 is formed below second mask portions 35.

Next, as shown in FIG. 11C poly-silicon film 37a is formed by depositing doped poly-silicon, such as poly-silicon containing phosphorus, on the entire surface of semiconductor substrate 11. Alternatively, poly-silicon may be deposited on the semiconductor substrate 11 and phosphorus ions may be implanted in the poly-silicon layer by ion implant methods.

Next, as shown in FIG. 11D, etch-back is applied and poly-silicon film 37a (shown in FIG. 11C) remains on the bottom of first trenches 17 and forms the field plate electrode 41.

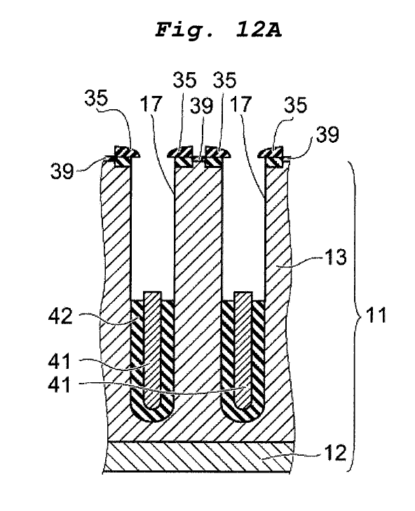

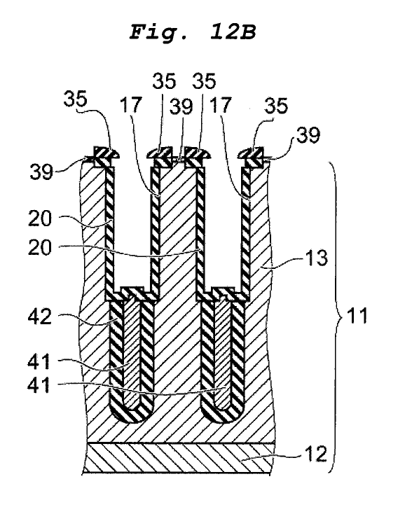

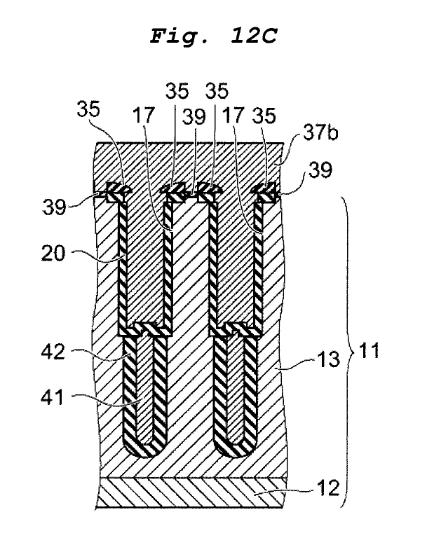

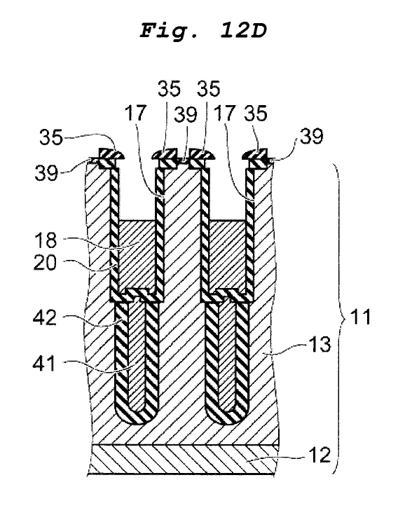

Next, as shown in FIG. 12A, etching is applied to remove a portion of field plate insulating film 42 that is located above the upper surface of field plate electrode 41. As a result, only a portion of field plate insulating film 42 below the upper surface of field plate electrode 41 will remain. During this etch procedure, the first mask portions 31 (shown in FIG. 11D) are removed as well. One or a combination of a wet etch and a dry etch may be utilized to remove the field plate insulating film 42 and/or the first mask portions 31.

As stated above, the width of first trench 17 is wider than the width of second open region 32b. Consequently, by removing field plate insulating film 42 formed below second mask portions 35, the edge of second mask portions 35 will project out in regions directly above first trenches 17.

Next, as shown in FIG. 12B, gate insulating film 20 is formed above the upper surface of the field plate electrode 41 within the interior of first trenches 17 and the upper surface of the field plate electrode 41 itself. Gate insulating film 20 is formed by, for example, applying heat treatment to thermally oxidize the interior surface of first trenches 17 and the upper surface of field plate electrode 41 therein.

Next, as shown in FIG. 12C, poly-silicon film 37b is formed on semiconductor substrate 11 and is embedded in first trenches 17 within the gate insulating film 20.

Next, as shown in FIG. 12D, etch-back is applied on the entire surface of semiconductor substrate 11 and poly-silicon film 37b (shown in FIG. 12C) remains on the bottom of first trenches 17 to form gate electrodes 18 above the field plate electrode 41.

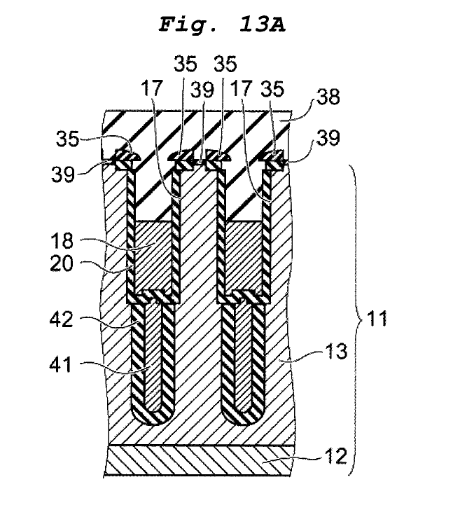

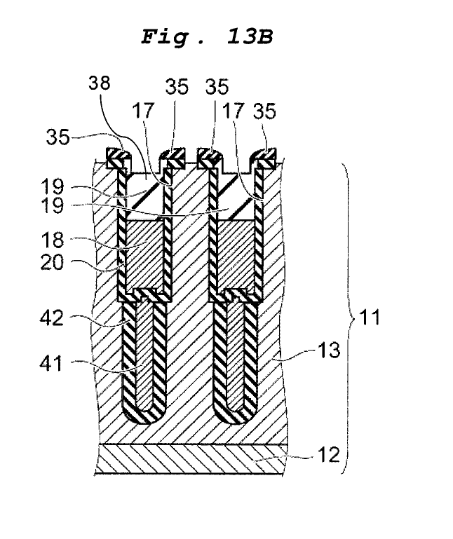

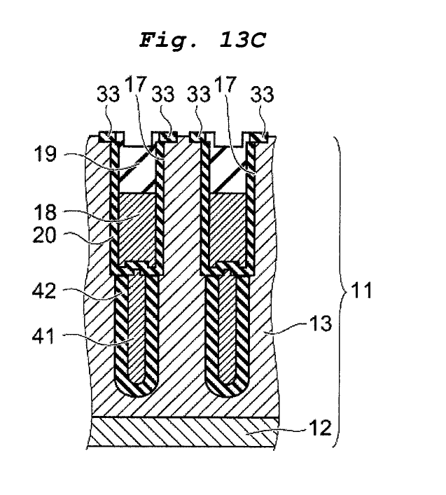

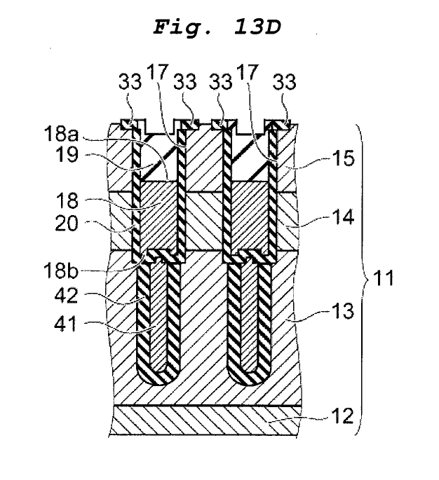

Next, as shown in FIG. 13A, silicon oxide film 38 is formed on semiconductor substrate 11 embedding the gate electrodes 18.

Next, as shown in FIG. 13B, etching is performed on the entire surface of semiconductor substrate 11 and silicon oxide film 38 remaining on the bottom of first trenches 17 forms insulating component layer 19 above gate electrodes 18. Additionally insulating film 39 (shown in FIG. 13A) above the upper surface of semiconductor substrate 11 is removed during the etching process.

Next, as shown in FIG. 13C, second mask portions 35 (shown in FIG. 13B) are removed by a stripping process. From this, the upper surface of insulating film 33 will be exposed.

And then, as shown in FIG. 13D, boron is ion implanted in semiconductor substrate 11 from above to form base layer 14 at the upper layer of semiconductor substrate 11.

Additionally, phosphorus is ion implanted in semiconductor substrate 11 from above to form source layer 15 above base layer 14.

Next, as shown in FIG. 14A, using insulating film 33 and insulating component layer 19 as masks, anisotropic etching is performed from above semiconductor substrate 11. From this, the section of semiconductor substrate 11 previously masked by first mask portions 31 (shown in FIG. 11D) is selectively removed, and second trenches 21 are formed stretching in one direction in upper portions of semiconductor substrate 11.

Next, using insulating film 33 and insulating component layer 19 as masks, boron is ion implanted in semiconductor substrate 11. From this, base contact layer 22 is formed at a region directly adjacent to and/or under the source layer 15 in base layer 14.

Next, as shown in FIG. 14B, etching is performed to remove portions of insulating component layer 19, gate insulating film 20, and insulating film 33 (shown in FIG. 14A). From this, upper surface 19a of insulating component layer 19 and upper end 20a of gate insulating film 20 is offset below upper surface 11a of semiconductor substrate 11 (i.e., below upper surface 15a of source layer 15). Additionally, an upper portion of lateral surfaces of first trenches 17 in source layer 15, as well as the upper surface 15a of source layer 15, will be exposed.

Next, as shown in FIG. 9, source electrode 25 is formed covering the upper surface of the semiconductor substrate 11. On the opposing side of semiconductor substrate 11, drain electrode 16 is formed on the bottom surface of semiconductor substrate 11. As shown in FIG. 9, the semiconductor device 2 is manufactured in this manner.

Next, the effect of this embodiment will be explained. According to this embodiment, semiconductor device 2 is installed with a field plate electrode 41. Therefore on-state resistance decreases and breakdown voltage is improved. The effects of this embodiment may be the same as the first embodiment with the additional benefits of the decreased on-state resistance as well as the improved breakdown voltage.

### Embodiment 4

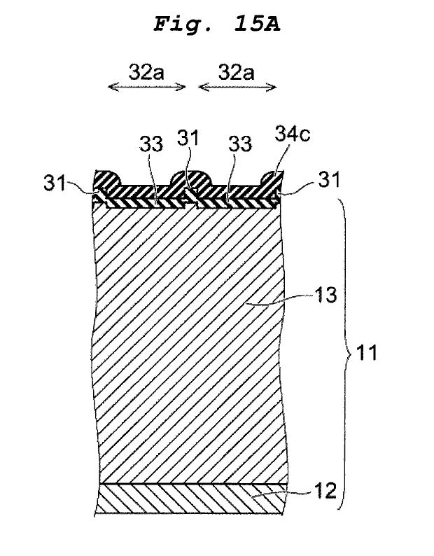

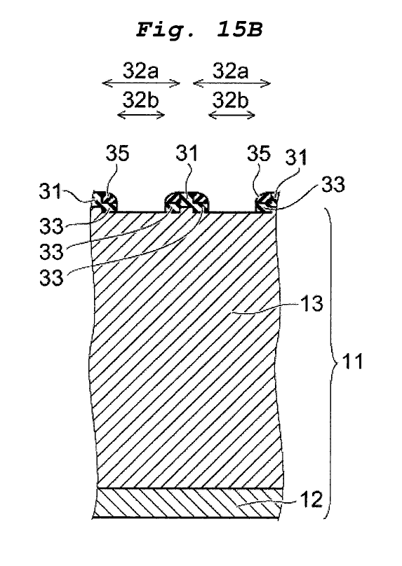

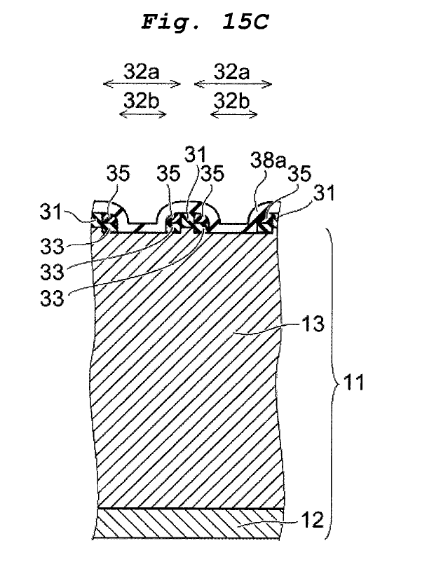

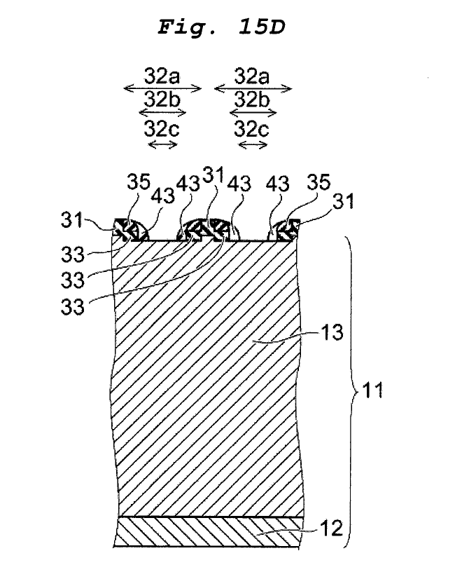

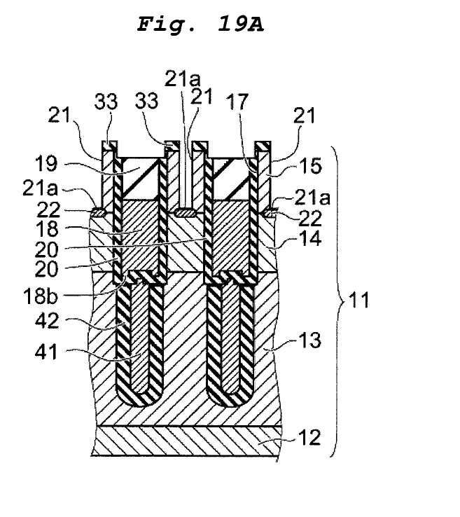

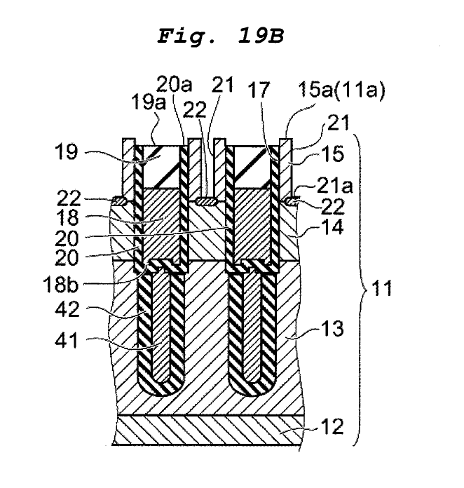

Next, embodiment 4 will be explained. FIGS. 15A to 15D, FIGS. 16A to 16D, FIGS. 17A to 17D, FIGS. 18A to 18D, along with FIGS. 19A and 19B are schematic sectional views showing the steps of a manufacturing method of the semiconductor device relating to the fourth embodiment, which is an alternative manufacturing method of the semiconductor device 2 relating to the third embodiment.

First, similar to the first embodiment, the process shown in FIGS. 2A and 2B will be utilized and an explanation of these procedures will be omitted for brevity. Next, as shown in FIG. 15A, silicon nitride film 34c is formed on the entire surface of semiconductor substrate 11. In this embodiment, the thickness of silicon nitride film 34c is less than the thickness of silicon nitride film 34b in the second embodiment. This silicon nitride film 34c covers insulating film 33 in the first open regions 32a as well as the first mask portions 31.

Next, as shown in FIG. 15B, etch-back is applied to remove the section of the silicon nitride film 34c (shown in FIG. 15A) formed above the upper surface of the first mask portions 31 and the section above the insulating film 33, the remainder of the silicon nitride film 34c being maintained on the lateral surface of first mask portions 31 to form second mask portions 35. Second mask portions 35 are formed on the lateral surface of first mask portions 31, and a second open region 32b is formed within first open region 32a. Then, insulating film 33 in the second open region 32b is removed using second mask portions 35 as a mask.

Next, as shown in FIG. 15C, silicon oxide film 38a is formed by depositing silicon oxide on the entire surface of the semiconductor substrate 11. Then, as shown in FIG. 15D, etch-back is performed to remove the section of the silicon oxide film 38a (shown in FIG. 15C) above the upper layer of first mask portions 31 and second mask portions 35 as well as the sections between the insulating film 33 remaining on semiconductor substrate 11 to form third mask portions 43 composed of silicon oxide on the second mask portions 35. Third mask portions 43 are formed on the lateral surfaces of second mask portions 35. A third open region 32c is formed within third mask portion 43 and the third mask portion 43 is within second open region 32b. Therefore, second mask portions 35 are formed on both sides of first mask portions 31, and third mask portions 43 are formed on the opposite lateral surfaces of insulating film 33 and second mask portions 35.

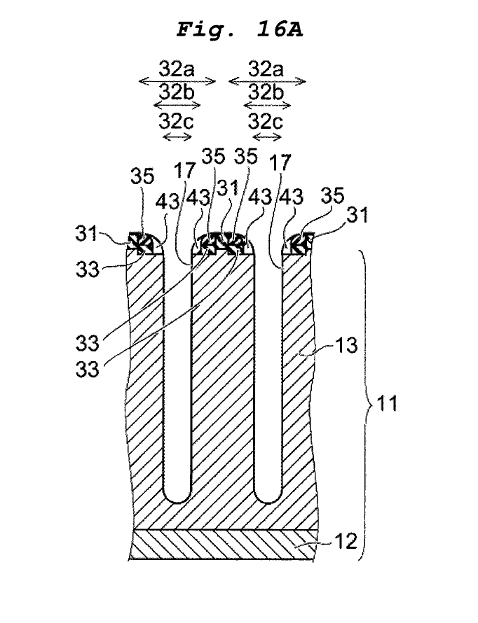

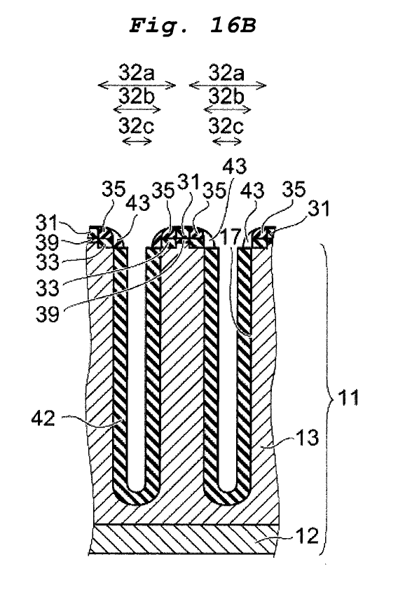

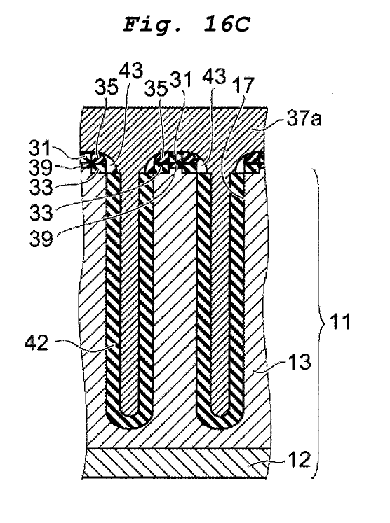

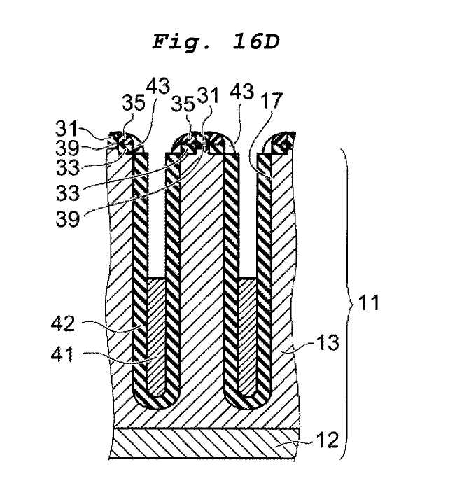

Next, as shown in FIG. 16A, by using first mask portions 31, second mask portions 35, and third mask portions 43 as masks, anisotropic etching, such as RIE, is performed to selectively remove portions of semiconductor substrate 11 in the region directly below the third open region 32c, which forms multiple first trenches 17 in equal intervals extending in one direction.

Next, as shown in FIG. 16B, field plate insulating film 42 is formed on the interior of first trench 17. During this time, the section covered by first mask portions 31 in the upper surface of semiconductor substrate 11 is also oxidized, forming insulating film 39. When field plate insulating film 42 is formed by thermal oxidation process, the lateral surface of first trenches 17 will be oxidized and eroded. Consequently, the width of trench 17 will be wider than the width of the third open region 32c.

However, in this embodiment, the lateral surface of each first trench 17 that is oxidized and eroded will be controlled. From this, the width of each first trench 17 is controlled to not be wider than the width of second open region 32b. That is, field plate insulating film 42 will be formed below second mask portions 35. For example, say semiconductor substrate 11 is silicon, assume the thickness increases 2.3 times when silicon becomes silicon oxide. In that case, the thickness of the field plate insulating film 42 to be formed will not exceed 2.3 times the thickness of the third mask portion 43 in the width direction.

Next, as shown in FIG. 16C, poly-silicon film 37a is formed by depositing impurity such as poly-silicon containing phosphorus on the entire surface of semiconductor substrate 11. This poly-silicon film 37a is embedded onto first trenches 17 and built up on the upper surface of first mask portions 31, second mask portions 35, and third mask portion 43.

Next, as shown in FIG. 16D, etch-back is applied and poly-silicon film 37 remains on the bottom of first trenches 17 to form field plate electrodes 41 therein.

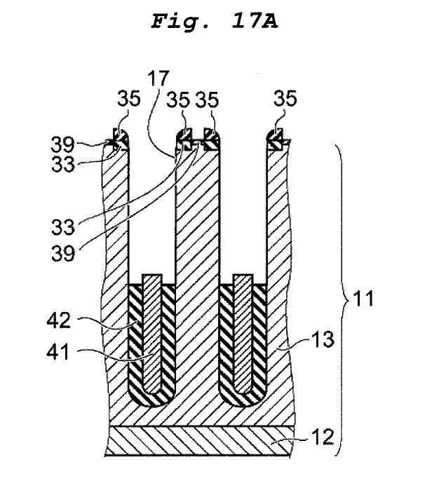

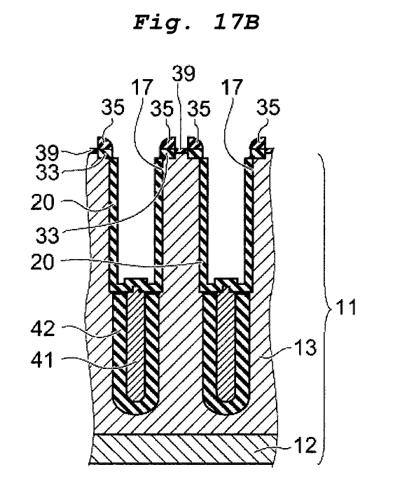

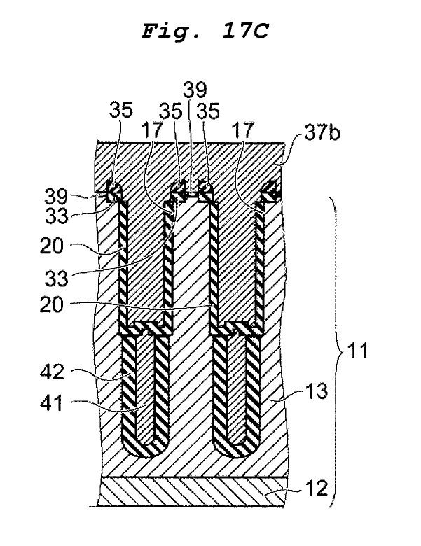

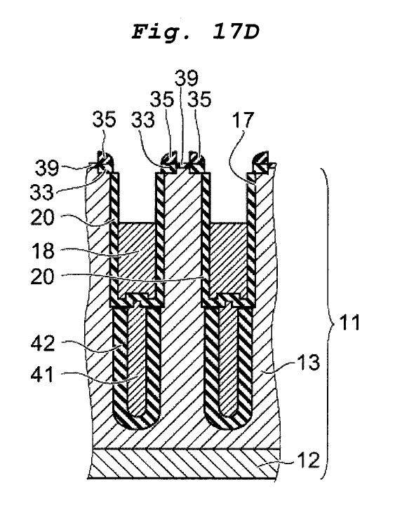

Next, as shown in FIG. 17A, etching is applied to remove the section of field plate insulating film 42 that is positioned above the upper surface of field plate electrode 41. As a result, only the portion of field plate insulating film 42 below the upper surface of field plate electrode 41 will remain. During this etching process, first mask portions 31 (shown in FIG. 16D) and third mask portions 43 (shown in FIG. 16D) are removed as well.

As stated above, in this embodiment, field plate insulating film 42 is not formed below second mask portions 35. Consequently, even by removing the section of field plate insulating film 42 that is positioned above the upper surface of field plate electrode 41, the edge of second mask portions 35 will not project into the region directly above the first trenches 17.

Next, as shown in FIG. 17B, gate insulating film 20 is formed above the upper surface of the field plate electrode 41 within the interior of each first trench 17 as well as the upper surface of the field plate electrode 41 itself.

Next, as shown in FIG. 17C, poly-silicon film 37b is formed on semiconductor substrate 11 by depositing conducting material such as poly-silicon containing phosphorus that covers the surface of semiconductor substrate 11 embedding first trenches 17. Next, as shown in FIG. 17D, etch-back is applied on the entire surface and poly-silicon film 37b (shown in FIG. 17C) remains on the bottom of first trench 17 to form gate electrodes 18 above the field plate electrodes 41.

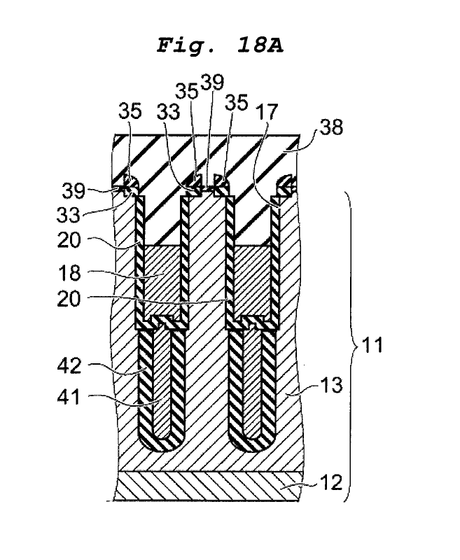

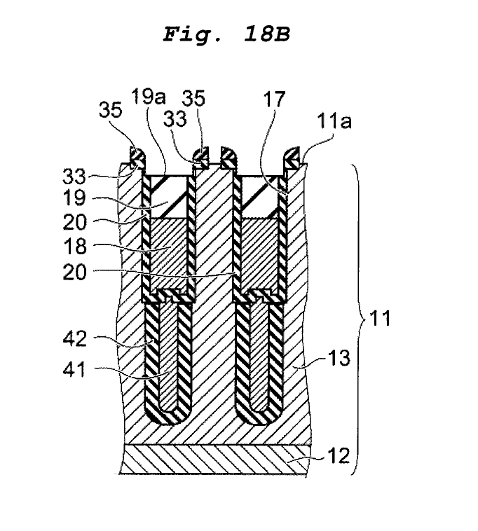

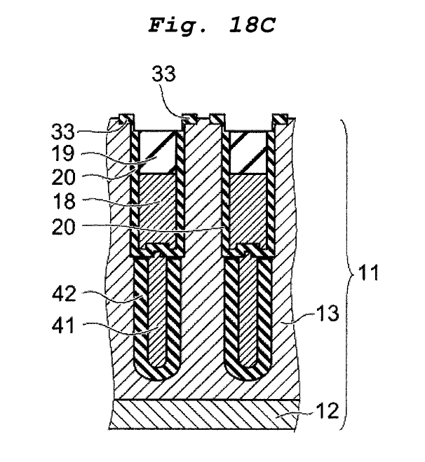

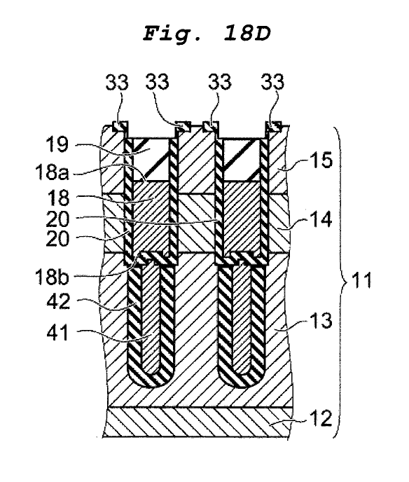

Next, as shown in FIG. 18A, silicon oxide film 38 is formed by depositing silicon oxide on the entire surface of semiconductor substrate 11 using methods such as CVD method. Next, as shown in FIG. 18B, etching is performed on the entire surface of semiconductor substrate 11 and silicon oxide film 38 (shown in FIG. 18A) remains within first trenches 17 to form insulating component layer 19 above gate electrodes 18. During this time, the upper surface 19a of insulating component layer 19 is below the upper surface 11a of semiconductor substrate 11. Additionally, insulating film 39 (shown in FIG. 18A) above the upper surface 11A of semiconductor substrate 11 is to expose the upper surface 11A of semiconductor substrate 11.

Next, as shown in FIG. 18C, second mask portions 35 (shown in FIG. 18B) are removed. From this, the upper surface of insulating film 33 will be exposed. And then, as shown in FIG. 18D, boron is ion implanted in semiconductor substrate 11 from above to form base layer 14 at the upper layer of semiconductor substrate 11. Additionally, phosphorus is ion implanted in base layer 14 from above to form source layer 15 at the upper layer of base layer 14.

Next, as shown in FIG. 19A, using insulating film 33, gate insulating film 20, and insulating component layer 19 as masks, anisotropic etching is performed on semiconductor substrate 11 from above. From this, the section covered by first mask portions 31 (shown in FIG. 16D) in semiconductor substrate 11 is selectively removed, and second trench 21 is formed extending in one direction from upper surface 11a of semiconductor substrate 11.

Next, using insulating film 33, gate insulating film 20, and insulating component layer 19 as masks, boron is ion implanted in semiconductor substrate 11. From this, base contact layer 22 is formed at a region directly above the base layer 14 and between source layer 15 and base layer 14.

Next, as shown in FIG. 19B, etch-back is applied to semiconductor substrate 11 to selectively remove upper part of insulating component layer 19, upper part of gate insulating film 20, and insulating film 33 (shown in FIG. 19A).

Next, as shown in FIG. 9, source electrode 25 is formed covering the upper surface of the semiconductor substrate 11. On the opposing side of semiconductor substrate 11, drain electrode 16 is formed on the bottom surface of semiconductor substrate 11. As shown in FIG. 9, the semiconductor device 2 is manufactured in this manner.

Next, the effect of this embodiment will be explained. In the previously described third embodiment, field plate insulating film 42 is formed below the second mask portions 35. Consequently, silicon nitride film 34b needs to be formed thicker for the second mask portions 35 to be fixed above source layer 15, in case a portion of the field plate insulating film 42 formed below the second mask portions 35 is removed.

In this embodiment, third mask portions 43 are formed on the lateral surface of second mask portions 35, and field plate insulating film 42 is formed below the third mask portions 43. Second mask portions 35 are fixed above source layer 15. Therefore, even if field plate insulating film 42 is removed, second mask portions 35 remain fixed above source layer 15. Because of that, the thickness of the silicon nitride film 34c used to form second mask portions 35, may be thinner than the thickness of silicon nitride film 34b in the third embodiment. From this, by silicon nitride film 34c covering the semiconductor substrate 11, stress in the semiconductor substrate 11 can be reduced. Additionally, the number of defects generated in semiconductor substrate 11 can be reduced.

Additionally, self-alignment of first trenches 17 can be realized using the masking procedures comprising the first mask portions 31, second mask portions 35, and third mask portions 43. Then, once the first mask portions 31 are formed using lithography methods, second mask portions 35 and third mask portions 43 may be formed that are self-aligned. Additionally, each first trench 17 for gate electrodes 18 and each second trench 21 for base contacts 22 may also be formed with this self-aligning procedure. During this process, the opening width of second trench 21 is controlled by the width of first mask portions 31, and the opening width of first trench 17 may be controlled by both the interval of first mask portions 31 and the width of second mask portions 35 and third mask portions 43.

In the embodiments explained above, an improved semiconductor device and its manufacturing method can be realized.

While certain embodiments have been described, these embodiments have been presented by way of example only, and are not intended to limit the scope of the inventions. Indeed, the novel embodiments described herein may be embodied in a variety of other forms, furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor layer having a first conductivity type;
a second semiconductor layer disposed on the first semiconductor layer, the second semiconductor layer having the first conductivity type and a dopant concentration that is less than a dopant concentration of the first semiconductor layer;
a base layer disposed on the second semiconductor layer, the base layer having a second conductivity type that is different than the first conductivity type;
a source layer having the first conductivity type disposed on the base layer;
a plurality of first trenches formed in the source layer and extending inwardly through the base layer and into the second semiconductor layer, each of the first trenches comprising a gate electrode; and
a plurality of second trenches disposed between the first trenches and electrically isolated from the first trenches, each of the plurality of second trenches extending inwardly through the source layer to form a base contact semiconductor layer that is in electrical contact with the base layer.

2. The device of claim 1, wherein the base contact semiconductor layer comprises the second conductivity type.

3. The device of claim 2, wherein the second conductivity type comprises a dopant concentration that is greater than a dopant concentration of the base layer.

4. The device of claim 1, wherein the base contact semiconductor layer comprises a dopant concentration that is greater than a dopant concentration of the base layer.

5. The device of claim 1, further comprising:
a plurality of field plate electrodes disposed in the second semiconductor layer below a respective gate electrode.

6. The device of claim 5, wherein each of the plurality of gate electrodes are electrically separated from a respective field plate electrode by an insulating film.

7. The device of claim 1, further comprising an insulative layer disposed on each gate electrode, wherein an upper surface of the insulative layer is disposed below an upper surface of the source layer.

8. The device of claim 1, further comprising a source electrode disposed on the source layer, wherein the source electrode comprises conductive layer and a metal film.

9. The device of claim 8, further comprising a drain electrode disposed on the first semiconductor layer opposite the source electrode.

10. A method for forming a semiconductor device, comprising:
forming a first semiconductor layer having a first conductivity type;
depositing a second semiconductor layer on the first semiconductor layer, the second semiconductor layer having the first conductivity type and a dopant concentration that is less than a dopant concentration of the first semiconductor layer;
forming a base layer and a source layer in the second semiconductor layer, the base layer having a second conductivity type that is different than the first conductivity type and the source layer having the first conductivity type;
forming a plurality of first trenches in the source layer and extending inwardly through the base layer and into the second semiconductor layer; and
forming a plurality of second trenches disposed between the first trenches and electrically isolated from the first trenches, each of the plurality of second trenches extending inwardly through the source layer to form a base contact semiconductor layer that is in electrical contact with the base layer.

11. The method of claim 10, wherein the base contact semiconductor layer comprises the second conductivity type and includes a dopant concentration that is greater than a dopant concentration of the base layer.

12. The method of claim 10, further comprising:
forming a plurality of field plate electrodes in the second semiconductor layer below a respective gate electrode.

13. A method for forming a semiconductor device, the method comprising:
forming a first semiconductor layer having a first conductivity type;
depositing a second semiconductor layer on the first semiconductor layer, the second semiconductor layer having the first conductivity type and a dopant concentration that is less than a dopant concentration of the first semiconductor layer;
depositing at least a first oxide layer on the second semiconductor layer;
depositing a nitride layer on the oxide layer;
etching the first oxide layer and the nitride layer to form a plurality of mask portions on the second semiconductor layer;
forming a plurality of first trenches in the second semiconductor layer by etching the second semiconductor layer;
forming a gate electrode in each of the plurality of first trenches;
depositing an insulative layer on the gate electrode;
implanting ions into the second semiconductor layer to form a first layer having a second conductivity type that is different than the first conductivity type and a second layer having the first conductivity type;
forming a plurality of second trenches in the third layer adjacent the plurality of first trenches;
forming a base contact region in each of the plurality of second trenches, each of the base contact regions having the second conductivity type and a dopant concentration that is greater than a dopant concentration of the first layer; and
depositing a conductive layer on the base contact regions and the second layer.

14. The method of claim 13, wherein the plurality of mask portions control the cross-sectional width of each of the plurality of first trenches during the etching.

15. The method of claim 14, wherein forming the gate electrodes comprises oxidizing sidewalls of each of the plurality of first trenches after the etching to form an insulating film on the sidewalls, wherein oxidizing the sidewalls increases the cross-sectional width of the sidewalls of each of the trenches to an opening dimension that is greater than an opening width between adjacent mask portions.

16. The method of claim 15, wherein, after the oxidizing, the insulating film comprises an opening width that is less than or equal to the opening width between the mask portions.

17. The method of claim 13, further comprising:
forming a field plate electrode in the plurality of first trenches prior to forming the gate electrodes, wherein the plurality of mask portions comprises a first mask portion comprising the first oxide layer and a plurality of second mask portions comprising a second oxide layer that control the cross-sectional width of each of the plurality of first trenches during the etching.

18. The method of claim 17, wherein forming the field plate electrode comprises oxidizing sidewalls of each of the plurality of first trenches after the etching to form a first insulating film on the sidewalls, wherein oxidizing the sidewalls increases the cross-sectional width of the sidewalls of each of the trenches to an opening dimension that is greater than an opening width between adjacent first and second mask portions.

19. The method of claim 18, wherein, after the oxidizing, the first insulating film comprises an opening width that is less than or equal to the opening width between the first and second mask portions.

20. The method of claim 18, further comprising:
oxidizing the sidewalls of the plurality of first trenches to form a second insulating film over an upper portion of the first insulating film, wherein the second insulating film comprises an opening dimension that is greater than an opening dimension of the second insulating film.
